(19) United States
(12) Patent Application Publication
(10) Pub. No.: US 2014/0211443 A1
(43) Pub. Date: Jul. 31, 2014

(54) ADAPTER FOR ARC RESISTANT MOTOR CONTROL CENTER

(71) Applicants: Ajit Pharne, Dekalb, IL (US); Pablo A. Medina Rios, Duluth, GA (US); Reid Barkley, Carol Stream, IL (US); John Kaminski, North Aurora, IL (US); Jeffrey D. Lord, Suwanee, GA (US); Felix Galvan, Saint Charles, IL (US)

(72) Inventors: Ajit Pharne, Dekalb, IL (US); Pablo A. Medina Rios, Duluth, GA (US); Reid Barkley, Carol Stream, IL (US); John Kaminski, North Aurora, IL (US); Jeffrey D. Lord, Suwanee, GA (US); Felix Galvan, Saint Charles, IL (US)

(73) Assignee: SIEMENS INDUSTRY, INC., Alpharetta, GA (US)

(21) Appl. No.: 13/873,667

(22) Filed: Apr. 30, 2013

Related U.S. Application Data
(60) Provisional application No. 61/756,941, filed on Jan. 25, 2013.

(51) Int. Cl. H05K 5/02

(52) U.S. Cl. CPC H05K 5/0247
USPC 361/807; 361/679.01; 29/525.01

(57) ABSTRACT

The arc-resistant MCC is provided with either the expansion chamber or the plenum. Arc flashes create pressure. Different arc-resistant MCC bases are used depending on whether the expansion chamber or the plenum is to be attached, as the expansion chamber and the plenum deal with the created pressure in different ways and are accordingly attached to the MCC base in different ways.

### RELATED APPLICATIONS

The present patent document claims the benefit of the filing date under 35 U.S.C. §119(e) of Provisional U.S. Patent Application Ser. No. 61/756,941, filed Jan. 25, 2013, which is hereby incorporated by reference.

### TECHNICAL FIELD

This disclosure relates in general to the field of motor control centers, and, more particularly, to arc resistant motor control centers (MCCs).

### BACKGROUND

MCCs are used in a number of industrial and commercial applications to house and interconnect motor control units via a common power bus. An MCC may be installed in a separate air-conditioned room or may be installed adjacent to a controlled motor or other equipment. An MCC may include one or more cabinet sections with the common power bus, and individual motor control units are plug-in mountable to the common power bus. MCCs may house variable frequency drives, programmable controllers, and metering, for example.

Arc flashes may result from faults at components within the MCC. An arc flash is the light and heat produced from the fault and may cause damage to surrounding equipment, fire or injury. The energy released in the fault blasts debris outward with a large force.

Depending on the demands of a customer, an arc-resistant MCC uses an expansion chamber (e.g., a pull box) with a pressure flap or a plenum duct assembly to vent the products of the arc flash out of the MCC. The expansion chamber with the pressure flap vents the products of the arc flash to the immediate vicinity of the MCC and/or the motor controlled. The plenum duct assembly carries the products of the arc flash to a location away from the MCC and/or the motor controlled.

The arc-resistant MCC is provided with either the expansion chamber or the plenum. Arc flashes create pressure. Different arc-resistant MCC bases are used depending on whether the expansion chamber or the plenum is to be attached, as the expansion chamber and the plenum deal with the created pressure in different ways and are accordingly attached to the MCC base in different ways. This results in stocking a number of different bases.

### SUMMARY

In order to increase adaptability of an MCC section such that a plenum and an expansion chamber are both usable with the arc-resistant MCC section based on needs of a customer, an adapter plate is provided on the arc-resistant MCC section. The adapter plate includes first connection locations and second connection locations. The plenum is mountable to the adapter plate at the first connection locations, and the expansion chamber is mountable to the adapter plate at the second connection location.

In one aspect, an adapter plate of an MCC is configured such that an expansion chamber and a plenum are mountable to the adapter plate. The adapter plate includes a frame including a top, a bottom, and at least one side. The at least one side at least partially defines an outer perimeter of the frame. The adapter plate also includes at least one opening extending from the top to the bottom. The at least one opening at least partially defines an inner perimeter of the frame. The adapter plate includes a plurality of first connection locations disposed along the frame. The plenum is mountable to the adapter plate at the plurality of first connection locations. The adapter plate also includes a plurality of second connection locations disposed along the frame. The expansion chamber is mountable to the adapter plate at the plurality of second connection locations.

In another aspect, an MCC is usable with an expansion chamber and a plenum. The MCC includes a housing including a top, a bottom, and at least one side. The MCC also includes an adapter plate supported by the housing at or adjacent to the top of the housing. The adapter plate includes a frame including a top, a bottom, at least one side, and at least one opening. The at least one side at least partially defines an outer perimeter of the frame. The at least one opening extends from the top to the bottom of the frame and at least partially defines an inner perimeter of the frame. The adapter plate also includes a plurality of first apertures extending through the frame. The plenum is mountable to the adapter plate via the plurality of first apertures. The adapter plate includes a plurality of second apertures extending through the frame. The expansion chamber is mountable to the adapter plate at the plurality of second apertures.

In yet another aspect a method of manufacturing an MCC is provided. The MCC includes a housing and an adapter plate. The housing includes a top, a bottom, and a plurality of sides. The adapter plate includes a frame. The method includes mounting the adapter plate to the top of the housing. An expansion chamber and a plenum are mountable to the adapter plate. The method also includes mounting the plenum to the adapter plate via a plurality of first fastener apertures spaced along the frame of the adapter plate, or mounting the expansion chamber to the adapter plate via a plurality of second fastener apertures spaced along the frame of the adapter plate.

The present invention is defined by the following claims, and nothing in this section should be taken as a limitation on those claims. Further aspects and advantages of the invention are discussed below in conjunction with the preferred embodiments and may be later claimed independently or in combination.

### BRIEF DESCRIPTION OF THE DRAWINGS

To provide a more complete understanding of the present disclosure and features and advantages thereof, reference is made to the following description, taken in conjunction with the accompanying figures, wherein like reference numerals represent like parts.

FIG. 1 illustrates a perspective view of one embodiment of an MCC with a plenum and a corresponding duct;

FIG. 2 illustrates a perspective view of one embodiment of an arc-resistant MCC with an expansion chamber and a corresponding flap;

FIG. 3 illustrates a perspective view of one embodiment of an arc-resistant MCC section with an adaptor or transition plate;

FIG. 4 illustrates a perspective view of the MCC section and the adapter plate of FIG. 3 with one embodiment of an expansion chamber mounted on the adapter plate;

FIG. 5 illustrates a perspective view of the arc-resistant MCC section and the adapter plate of FIG. 3 with one embodiment of a plenum mounted on the adapter plate;

FIG. 6 illustrates a perspective view of one embodiment of an adapter plate;

FIG. 7 illustrates a top view of one embodiment of an adapter plate; and

FIG. 8 illustrates a flow chart of one embodiment of a method of manufacturing an MCC.

### DETAILED DESCRIPTION OF THE DRAWINGS

A top portion of an MCC section or base is configured differently based on the device (e.g., an expansion chamber or a plenum) to be mounted on the top portion of the MCC. For example, due to differences in pressure, the plenum uses more mounting points or a stronger connection.

To allow use of one arc-resistant MCC section for either the expansion chamber or the plenum, an adapter plate is provided. Using the adapter plate standardizes the MCC configuration for use with both the expansion chamber and the plenum.

The adapter plate is positioned on the top portion of the MCC section (e.g., a housing of the MCC section). The adaptor plate mounts to the top portion of the MCC section with screws, nuts and bolts, rivets, and/or other types of connections. The mounting is performed during manufacture of the MCC section. Alternatively, the adaptor plate is formed as part of or integral with the housing of the MCC section. In another alternative, the adapter plate is added in a retrofit.

The adapter plate includes first mounting holes that extend through the adapter plate and are positioned along the adapter plate. The plenum is mountable to the MCC section via the adapter plate at the first mounting holes using, for example, screws. The adapter plate also includes second mounting holes that extend through the adapter plate and are positioned along the adapter plate. The expansion chamber is mountable to the MCC section via the adapter plate at the second mounting holes using, for example, screws. Some holes may be used for both the plenum and the expansion chamber, and other holes may be specific to one or the other.

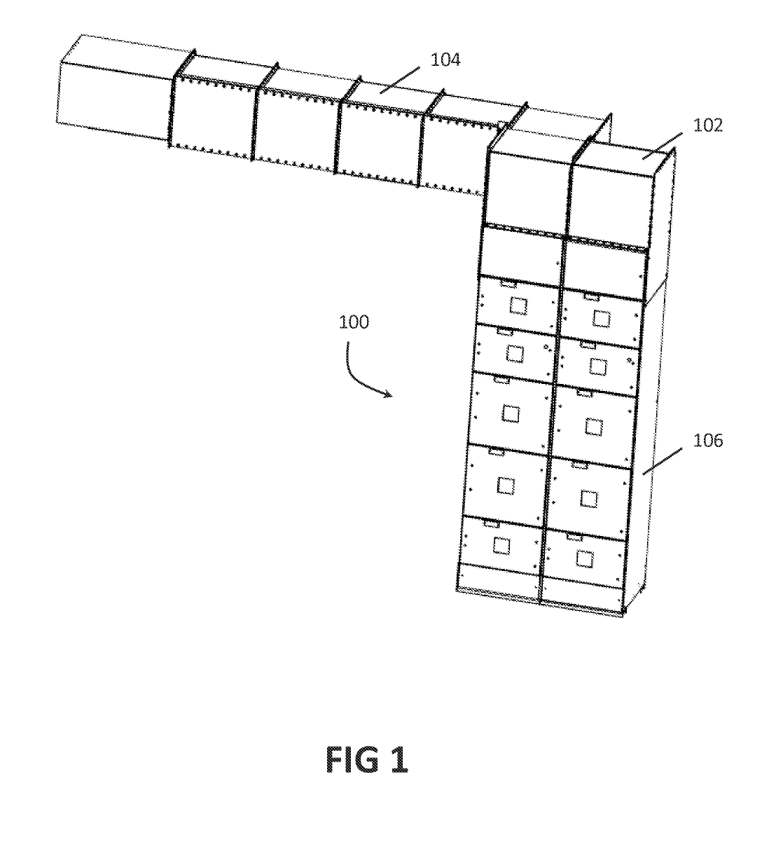

FIG. 1 shows a perspective view of one embodiment of an arc-resistant MCC 100 with a plenum 102 and a corresponding duct 104. The arc-resistant MCC 100 includes, for example, two MCC sections or bases 106. A top portion of each of the MCC sections 106 supports the plenum 102 and the duct 104. In other embodiments, the arc-resistant MCC 100 may include more or fewer MCC sections 106 (e.g., one MCC section).

Each MCC section 106 houses and supports one or more motor control units (not shown). For example, each MCC section 106 houses and supports variable frequency devices, programmable controllers, metering, or combinations thereof. In some embodiments, each motor control unit includes a contactor or a solid-state motor controller, overload relays to protect the motor, fuses or a circuit breaker to provide short-circuit protection, a disconnecting switch to isolate a motor circuit, or combinations thereof. The MCC sections 106 may include a common power bus, to which the one or more control units are mountable (e.g., pluggable).

The arc-resistant MCC 100 may be configured for one or more low voltage three-phase alternating current motors from, for example, 208 V to 600 V. Alternatively, the arc-resistant MCC 100 may be configured for one or more large motors running at, for example, 2300 V to approximately 15,000 V. The one or more motors may be wired to terminals in the one or more control units. In other embodiments, the arc-resistant MCC 100 may be configured for other equipment or machinery.

The MCC 100 may be installed in the same room or a different room than the one or more motors controlled by the MCC 100. For example, the MCC 100 may be installed in the same room as the one or more motors, adjacent to the one or more motors. Alternatively, the MCC 100 may be installed in a separate air-conditioned room remote from the one or more motors.

The plenum 102 is configured to transfer products of an arc flash (e.g., molten metal, particulate matter, heat, and smoke) away from the immediate vicinity of the one or more motors and/or the arc-resistant MCC 100, for example. The plenum 102 carries and exhausts the products of the arc flash to a safer location (e.g., a remote location outside of the room in which the one or more motors and/or the arc-resistant MCC is installed). The plenum 102 provides protection for personnel and the one or more motors that may be adjacent to the arc-resistant MCC 100 when the arc flash occurs.

One end of the duct 104 is attached to the plenum 102 and the other end of the duct 104 is attached to a pressure relief valve, for example. In one embodiment, a minimum cross-section of the duct 104 may be 270 square inches, and at least one dimension of the cross-section is at least 15 inches. Other dimensions may be provided so as to provide suitable pressure relief. The duct 104 may be made of, for example, 13 gauge steel. In other embodiments, the duct 104 may be an HVAC duct made per ASHRAE standards and may be made of other materials such as, for example, 24 gauge steel. The duct 104 may include one or more turns between the plenum 102 and the pressure relief valve. The duct 104 may be any number of lengths and may be oriented in any number of directions.

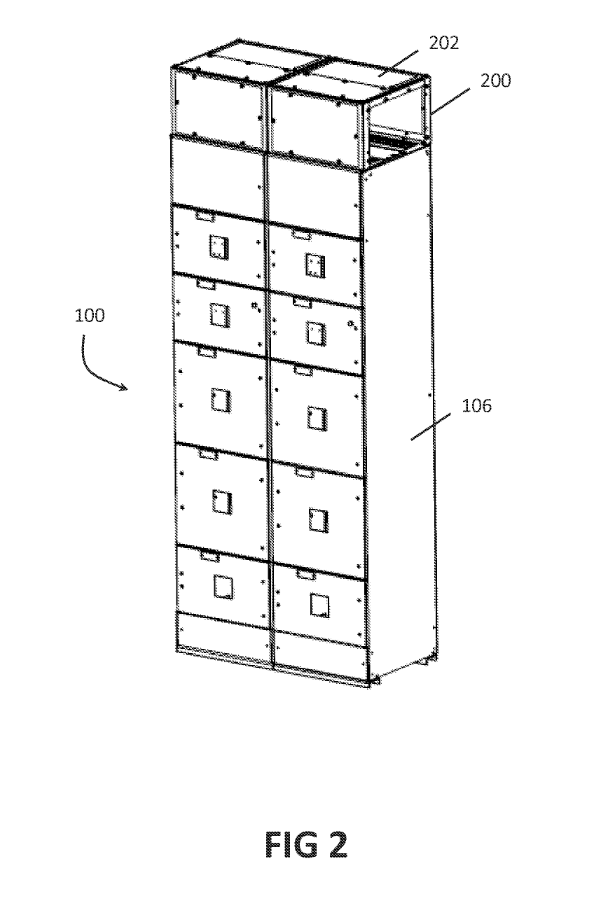

FIG. 2 shows a perspective view of one embodiment of an arc-resistant MCC 100 with an expansion chamber 200 and corresponding flaps 202. The arc-resistant MCC 100 includes the two MCC sections 106 but may include other numbers of sections. Top portions of the MCC sections 106 support the expansion chamber 200 (e.g., a pull box). The expansion chamber 200 includes the flaps 202, through which the products of the arc flash are expelled from the MCC 100. The flaps 202 provide pressure relief when the arc flash occurs.

The expansion chamber 200 exhausts the products of the arc flash in the immediate vicinity of the MCC 100 instead of carrying and exhausting the products of the arc flash to another location. Accordingly, the space adjacent to the MCC 100 should be kept clear of personnel and other flammable material.

In the prior art, MCC sections are configured for only the plenum 102 or for only the expansion chamber 200. With such a configuration, a customer who has purchased MCC sections of the prior art configured for the expansion chamber 200 may not later uninstall the expansion chamber 200 and retrofit the MCC sections with the plenum 102. Instead, the customer orders other MCC sections of the prior art configured for the plenum 102. This is expensive for the customer and may require the customer to store both MCC sections configured for the expansion chamber 200 and MCC sections configured for the plenum 102.

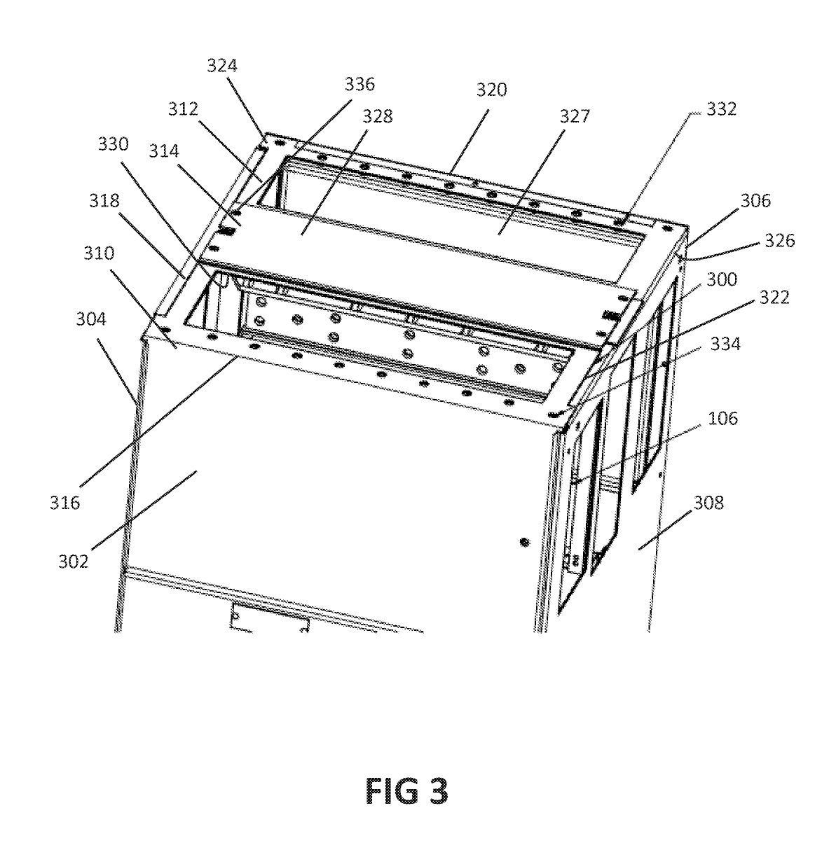

FIG. 3 shows a perspective view of one embodiment of an arc-resistant MCC section 106 with an adaptor or transition plate 300. The MCC section 106 includes a first side 302, a second side 304, a third side 306, a fourth side 308, a top 310, and a bottom (see FIGS. 1 and 2). The adaptor plate 300 includes a frame 312 and a support plate 314. The frame 312 includes a first side 316, a second side 318, a third side 320, a fourth side 322, a top 324, a bottom 326, and at least one opening 327 (e.g., two openings) extending from the top 324 to the bottom 326 of the frame 312. The first side 316, the second side 318, the third side 320, and the fourth side 322 of the frame 312 at least partially define an external perimeter of the adaptor plate 300. The at least one opening 327 at least partially defines an inner perimeter of the adaptor plate 300. The MCC section 106 and the adaptor plate 300 are both rectangular in shape. The MCC section 106 and the adaptor plate 300 may each include more or fewer sides and may be any number of other shapes including, for example, circular. The adaptor plate 300 (e.g., the frame 312 and the support plate 314) is made of any number of materials including, for example, 13 gauge steel. In one embodiment, the adaptor plate 300 is made of a different gauge steel (e.g., 15 gauge steel).

The support plate 314 includes a top 328 and a bottom 330. The support plate 314 extends from at or adjacent to the second side 318 of the adaptor plate 300 to at or adjacent to the fourth side 322 of the adaptor plate 300. The support plate 314 is, for example, rectangular in shape. The support plate 314 may also be other shapes. The support plate 314 may be provided to clear a structural part in the MCC section 106. In one embodiment, the frame 312 and the support plate 314 are manufactured from a single piece of material. In another embodiment, the frame 312 and the support plate 314 are separate parts and are connected together using, for example, screws. In one embodiment, the adaptor plate 300 does not include the support plate 314.

The frame 312 includes a plurality of first connection locations 332 and a plurality of second connection locations 334 positioned around the frame 312. In one embodiment, the frame 312 includes a plurality of third connection locations 336 positioned around the frame 312. For example, some of the first connection locations 332 may be positioned adjacent to the first side 316 of the adaptor plate 300. This group of first connection locations 332 may be positioned, for example, along a straight line parallel to the first side 316 of the adaptor plate 300. Others of the first connection locations 332 may be positioned adjacent to the third side 320 of the adaptor plate 300. These other first connection locations 332 may be positioned, for example, along a straight line parallel to the third side 320 of the adaptor plate 300.

Some of the second connection locations 334 may be positioned adjacent to the second side 318 of the adaptor plate 300. This group of second connection locations 334 may be positioned, for example, along a straight line parallel to the second side 318 of the adaptor plate 300. Others of the second connection locations 334 may be positioned adjacent to the fourth side 322 of the adaptor plate 300. These other second connection locations 334 may be positioned, for example, along a straight line parallel to the fourth side 322 of the adapter plate 300. The first connection locations 332 may be spaced evenly relative to one another along the first side 316 and the third side 320 of the adaptor plate 300, respectively. The second connection locations 334 may be spaced evenly relative to one another along the second side 318 and the fourth side 322 of the adaptor plate 300, respectively. In other embodiments, the first connection locations 332 and/or the second connection locations 334 may be positioned around the frame 312 in different configurations.

The third connection locations 336 may be positioned adjacent to the second side 318 and the fourth side 322 of the adaptor plate. The third connection locations 336 may, for example, be split evenly between the second side 318 and the fourth side 322 of the adaptor plate. In other embodiments, the third connection locations 336 may be positioned around the frame 312 in different configurations.

In one embodiment, the first connection locations 332 and the second connection locations 334 are fastener apertures or holes extending at least partially through the frame 312. The first fastener apertures 332 and the second fastener apertures 334 may extend in a direction perpendicular to the top 324 and/or the bottom 326 of the frame 312. The first fastener apertures 332 and the second fastener apertures 334 may be threaded or unthreaded. The first fastener apertures 332 and the second fastener apertures 334 may have any number of diameters and lengths. In one embodiment, the diameter of each of the first fastener apertures 332 and the second fastener apertures 334 is 5/16 inch. The first fastener apertures 332 may include any number of first fastener apertures. The first fastener apertures 332 may include, for example, 16 first fastener apertures 332 or 32 fastener apertures 332, split evenly between the first side 316 and the second side 320. In one embodiment, the number of first fastener apertures 332 is based on the width of the MCC section 106. There may be any number of second fastener apertures. The second fastener apertures 334 may include, for example, four second fastener apertures 334, split evenly between the second side 318 and the fourth side 322.

In one embodiment, the third connection locations 336 are fastener apertures or holes at least partially extending through the frame 312 and/or the support plate 314. The third fastener apertures 336 may extend in a direction perpendicular to the top 324 and/or the bottom 326 of the frame 312. The third fastener apertures 336 may be threaded or unthreaded. The third fastener apertures 336 may have any number of diameters and lengths. In one embodiment, the diameter of each of the third fastener apertures 336 is 5/16 inch. There may be any number of third fastener apertures 336 (e.g., four third fastener apertures).

The bottom 326 of the frame 312 is disposed on the top 310 of the MCC section 106. The frame 312 is positioned on the MCC section 106 such that one or more of the sides 316, 318, 320, 322 of the adaptor plate 300 are flush with one or more of the sides 302, 304, 306, 308 of the MCC section 106, respectively. The top 310 of the MCC section 106 may include one or more flanges extending from one or more of the sides 302, 304, 306, 308 of the MCC section 106. The adaptor plate 300 may be supported by the one or more flanges at the top 310 of the MCC section 106. Alternatively, the adaptor plate 300 is formed as part of or integral with the MCC section 106 or supported by another portion.

In one embodiment, the adaptor plate 300 is mounted to the top 310 of the MCC section 106 via the third fastener apertures 336 and corresponding fastener apertures in the flanges at the top 310 of the MCC section 106. In another embodiment, the adaptor plate 300 is mounted to the top 310 of the MCC section 106 via at least some fastener apertures of the first fastener apertures 332 and the second fastener apertures 334, and corresponding fastener apertures in the flanges at the top 310 of the MCC section 106. For example, the adaptor plate 300 may be mounted to the top 310 of the MCC section 106 via the third fastener apertures 336 and the second fastener apertures 334. In other words, the expansion chamber 200 is mounted to the adapter plate 300, and the adapter plate 300 is mounted to the top 310 of the MCC section 106 using, for example, machine screws through the second fastener apertures 334.

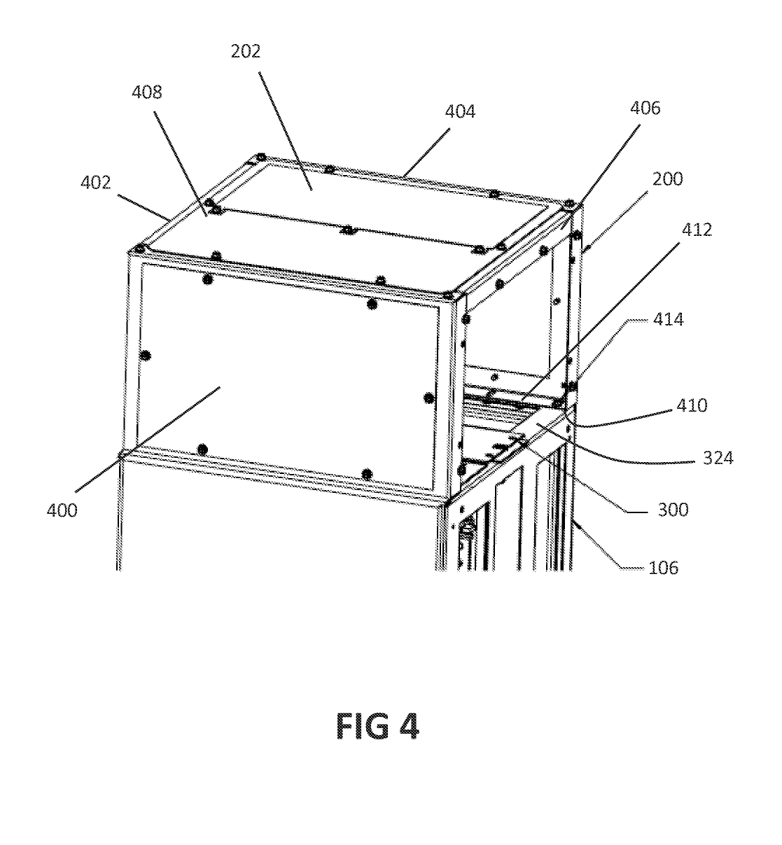

FIG. 4 shows a perspective view of the MCC section 106 and the adapter plate 300 of FIG. 3 with one embodiment of the expansion chamber 200 mounted on the adapter plate 300. The expansion chamber 200 includes a first side 400, a second side 402, a third side 404, a fourth side, 406, a top 408, and a bottom 410. The top 408 of the expansion chamber 200 may include the flap 202 such that the products of the arc flash may be expelled from the MCC section 106. The flap 202 may be hinged to a portion of the top 408 of the expansion chamber 200 such that the flap 202 may open based on the pressure within the expansion chamber 200.

The first side 400 and the third side 404 of the expansion chamber 200, for example, include flanges 412 abutting or disposed adjacent to the top 324 of the adaptor plate 300 when the expansion chamber 200 is supported by the adaptor plate 300. For example, the first side 400 of the expansion chamber 200 includes a flange 412 that extends in a direction perpendicular to the first side 400 and towards the third side 404 of the expansion chamber. The third side 404 of the expansion chamber 200 includes a flange 412 that extends in a direction perpendicular to the third side 404 and towards the first side 400 of the expansion chamber 200. The expansion chamber 200 may include additional flanges that provide support for the expansion chamber 200 when the expansion chamber 200 is supported by the adaptor plate 300.

The flanges 412 include apertures 414 corresponding to the second fastener apertures 334 when the expansion chamber 200 is aligned with the adaptor plate 300. The apertures 414 may extend through the flanges 412. The apertures 414 may be the same size or a different size than the second fastener apertures 334. The flanges 412 may include the same number of apertures 414 as the number of second fastener apertures 334 extending through the adaptor plate 300. Alternatively, the flanges 412 may include more or fewer apertures 414 than the number of second fastener apertures 334 extending through the adaptor plate 300.

The expansion chamber 200 may be mounted to the adaptor plate 300 in any number of ways including, for example, with four ¼-20 machine screws via the second fastener apertures 334 in the adaptor plate 300 and the apertures 414 in the expansion chamber 200. In other embodiments, nuts and bolts, rivets, and/or other types of connectors may be used to mount the expansion chamber 200 to the adaptor plate 300. Different sized machine screws (e.g., 5/16-18) may be used to mount the expansion chamber 200 to the adaptor plate 300. More or fewer connectors may be used to mount the expansion chamber 200 to the MCC section 106 via the adaptor plate 300.

The embodiment of the MCC section 106 shown in FIG. 4 includes an opening at the second side 402 and the fourth side 406 of the expansion chamber 200. In one embodiment, if the MCC 100 includes a plurality of MCC sections 106 (e.g., three MCC sections) with expansion chambers, the MCC section 106 shown in FIG. 4 may be a middle MCC section (e.g., a second MCC section) of the three MCC sections 106. An expansion chamber of a first MCC section of the three MCC sections 106 may be closed at the first side 400, the second side 402, and the third side 404, and may be open at the fourth side 406. An expansion chamber of a third MCC section of the three MCC sections 106 may be closed at the first side 400, the third side 404, and the fourth side 406, and may be open at the second side 402. The first MCC section 106 and the third MCC section 106 may abut the second MCC section 106, and the expansion chamber 200 may be formed by the individual expansion chambers supported by each of the three MCC sections 106. The individual expansion chambers may be mounted to each other, such that the individual expansion chambers form a single large expansion chamber 200 with flaps 202. With such a configuration, the products of the arc flash are expelled from the MCC, through the flaps 202, not out any of the sides 400, 402, 404, 406 of the expansion chamber 200. In another embodiment, the expansion chambers of the first MCC section 106 and the third MCC section 106, for example, are configured similarly or the same as the expansion chamber 200 shown in FIG. 4, and the products of the arc flash may be expelled from the MCC, through the flaps 202, and any open sides 402, 406.

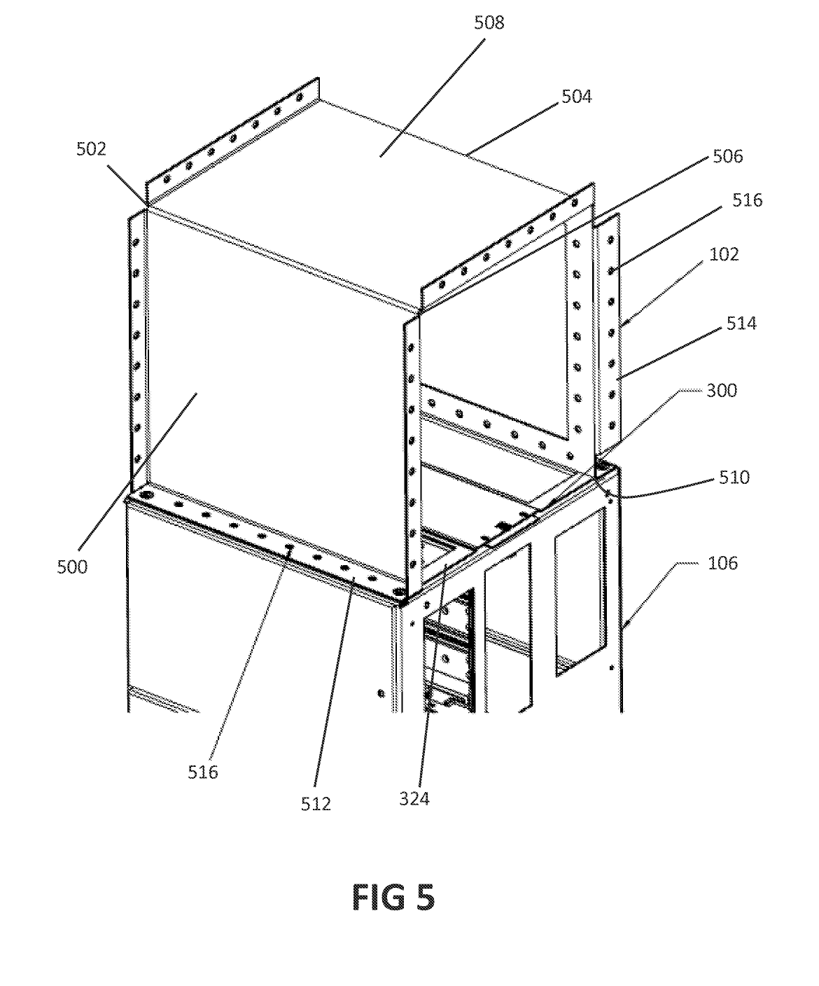

FIG. 5 shows a perspective view of the arc-resistant MCC section 106 and the adapter plate 300 of FIG. 3 with one embodiment of a plenum 102 mounted on the adapter plate 300. The plenum 102 includes a first side 500, a second side 502, a third side 504, a fourth side, 506, a top 508, and a bottom 510.

The first side 500 and the third side 504 of the plenum 102, for example, include flanges 512 adjacent to the bottom 510 of the plenum 102 and abutting or disposed adjacent to the top 324 of the adaptor plate 300 when the plenum 102 is supported by the adaptor plate 300. For example, the first side 500 of the plenum 102 includes a flange 512 that extends in a direction perpendicular to the first side 500 and away from the third side 504 of the plenum 102. The third side 504 of the plenum 102 includes a flange 512 that extends in a direction perpendicular to the third side 504 and away from the first side 500 of the plenum 102. The plenum 102 may include additional flanges 514 that facilitate the attachment of plenum sections together. The additional flanges 514 include apertures 516 for the attachment of the plenum sections. The apertures 516 in the additional flanges may be arranged in any number of ways, may be any number of shapes, and/or may be any number of sizes. Additional flanges 514 of plenum sections of adjacent MCC sections 106 may be connected in any number of ways including, for example, with machine screws through the apertures 516, nuts and bolts, rivets, and/or other types of connectors. In one embodiment, the additional flanges 514 do not include apertures 516, and the additional flanges 514 are welded together.

As an example, the first side 500 of the plenum 102 may include two additional flanges 514 that run from the top 508 to the bottom 510 of the plenum 102 in a direction perpendicular to the top 508 and/or the bottom 510 of the plenum 102. The two additional flanges 514 of the first side 500 may extend in a direction away from the first side 500 and may be disposed adjacent to the second side 502 and the fourth side 506, respectively. The top 508 and the third side 504, for example, may each include two additional flanges 514, for example, in line with the additional flanges 514 of the first side 500.

The flanges 512 include apertures 516 corresponding to the plurality of first fastener apertures 332 when the plenum 102 is aligned with the adaptor plate 300. The apertures 516 may extend through the flanges 512. The apertures 516 may be the same size or a different size than the plurality of first fastener apertures 332. The flanges 512 may include the same number of apertures 516 as the number of first fastener apertures 332 extending through the adaptor plate 300. Alternatively, the flanges 512 may include more or fewer apertures 516 than the number of first fastener apertures 332 extending through the adaptor plate 300.

The plenum 102 may be mounted to the adaptor plate 300 in any number of ways including, for example, with 16 or 26 5/16-18 machine screws through the plurality of first fastener apertures 332 in the adaptor plate 300 and the apertures 516 in the expansion chamber flanges 512. Nuts and bolts, other sized machine screws, rivets, and/or other types of connectors may be used to mount the plenum 102 to the adaptor plate 300. More or fewer connectors may be used to mount the plenum 102 to the MCC section 106 via the adaptor plate 300.

The embodiment of the MCC section 106 shown in FIG. 5 includes an opening at the second side 502 and the fourth side 506 of the plenum 102. In one embodiment, if the MCC 100 includes a plurality of MCC sections 106 (e.g., three MCC sections) with plenum sections, the MCC section 106 shown in FIG. 5 may be a middle MCC section (e.g., a second MCC section) of the three MCC sections 106. A plenum section of a first MCC section of the three MCC sections 106 may be closed at the first side 500 and the second side 502, for example. The third side 504 and the fourth side 506 of the plenum section of the first MCC section 106, for example, may be open. The third side 504 of the plenum section of the first MCC section 106, for example, may be connected to the duct 104 with any number of connectors including, for example, screws, nuts and bolts, rivets, welds, or any other connector. A plenum section of a third MCC section of the three MCC sections 106 may be closed at the first side 500, the third side 504, and the fourth side 506, and may be open at the second side 502.

The first MCC section 106 and the third MCC section 106 may abut the second MCC section 106, and the plenum 102 may be formed by the plenum sections supported by each of the three MCC sections 106. The individual plenum sections may be mounted to each other, such that the individual plenum sections form a single plenum 102. With such a configuration, the products of the arc flash are expelled from the MCC, through the open third side 504 of the plenum section of the first MCC section 106, through the duct 104, and out the pressure release valve attached to the end of the duct 104. Any side 500, 502, 504, 506 of the plenum sections may be open, and the duct 104 may be mounted at the open side. For example, the second side 502 of the first plenum section may be open, and the duct 104 may be mounted at the second side 502 of the first plenum section. The size of the opening may be the same as or greater than the size of an internal opening of the duct 104, so that travel of a pressure wave, smoke, and gasses generated by the arc flash is not hindered. A lesser size may be used. The duct 104 may be mounted to other plenum sections of the MCC 100.

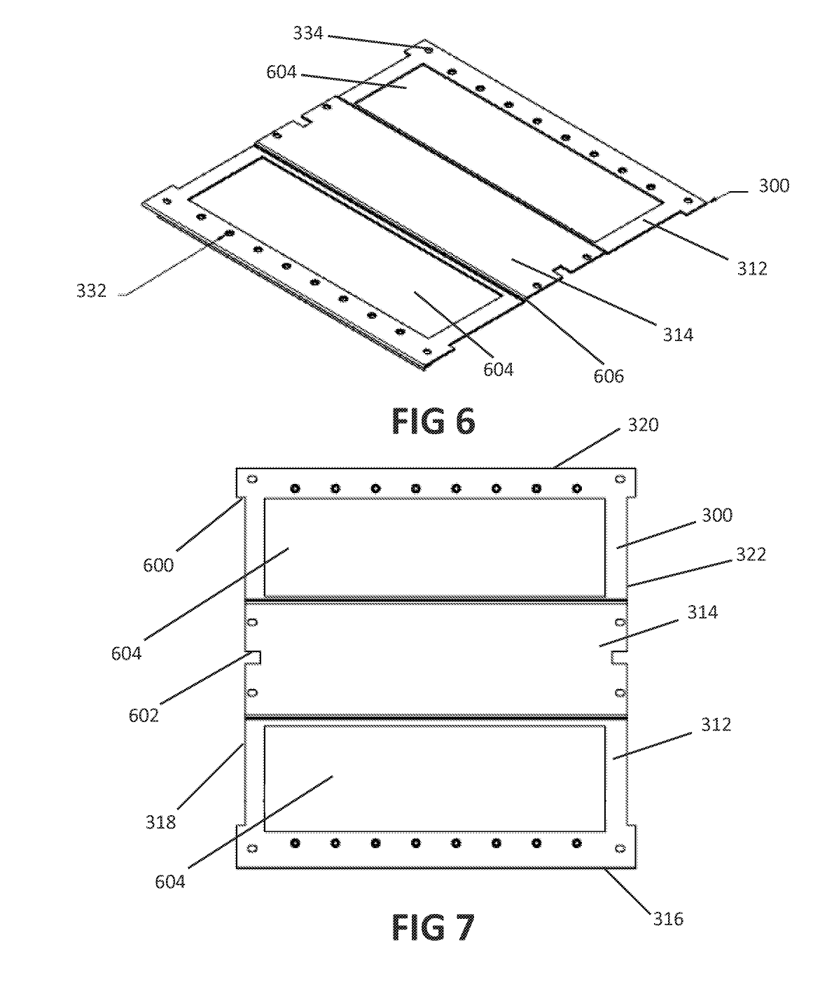

FIG. 6 shows a perspective view of one embodiment of an adapter plate 300, and FIG. 7 shows a top view of the adapter plate 300 of FIG. 6. The adapter plate 300 includes the frame 312 and the support plate 314. The frame 312 and the support plate 314 may, for example, be made from a single piece of material. Alternatively, the frame 312 and the support plate 314 may be made from separate parts. The adapter plate 300 may have a constant or a varying thickness. In one embodiment, the thickness of the adapter plate 300 is sized based on the size of the MCC section 106 to which the adapter plate 300 is to be mounted. For example, the adapter plate 300 may have a greater thickness when the area of the cross section of the MCC section 106 is greater.

The first side 316, the second side 318, the third side 320, and the fourth side 322 of the adapter plate 300 at least partially define an outer perimeter of the adapter plate 300. The first side 316 and the third side 320, for example, may extend in straight lines parallel to one another. The second side 318 and the fourth side 322 may extend such that one or more indentations and/or notches are defined. For example, the second side 318 may extend such that an indentation 600 and a notch 602 are formed. The indentation 600 and the notch 602 may be provided to match the shape of the MCC section 106 to which the adapter plate 300 is mounted. Projections (e.g., extensions, tabs, ridges) from the top 310 of the MCC section 106 may be positioned into the indentation 600 and the notch 602 of the adapter plate 300 when the adapter plate 300 is mounted on the MCC section 106. The projections may abut the second side 318 in the indentation 600 and the notch 602, respectively. Such a positioning may prevent the adapter plate 300 from sliding away from the MCC section 106 in any direction. The second side 318 and the fourth side 322 may mirror each other. In other embodiments, the adapter plate 300 may be shaped differently. In one embodiment, the adapter plate 300 may be square-shaped or rectangular, with the first side 316, the second side 318, the third side 320, and the fourth side 322 being straight lines.

In the embodiment shown in FIG. 6 and FIG. 7, the adapter plate 300 includes two openings 604. The products of the arc flash are expelled from the MCC section 106 through the two openings 604. The two openings 604 at least partially define an internal perimeter (e.g., made up of two individual internal perimeters) of the adapter plate 300. The two openings 604 may each, for example, be rectangular in shape. The size of each of the two openings 604 may be maximized while the adapter plate 300 still provides sufficient support for the plenum 102 and the expansion chamber 200. The greater the size of the openings 604, the less the adapter 300 restricts the flow of the products of the arc flash. In other embodiments, more or fewer openings may be provided (e.g., one opening), the openings may be different shapes, the openings may be different sizes, or a combination thereof.

The adapter plate 300 may include a raised portion 606. For example, the bottom 326 of the adapter plate 300 at and adjacent to the second side 318 and the fourth side 322, respectively, may be higher at the raised portion 606 than at and adjacent to the first side 316 and the third side, for example. The raised portion 606 may be provided such that the adapter plate 300 extends over components projecting out of the MCC section 106. The raised portion 606 may include the support plate 314 and a portion of the frame 312. The frame 312 and the support plate 314 may overlap at the raised portion 606 of the adapter plate 300.

In one embodiment, the adapter plate 300 includes two separate frames and does not include the support plate 314. The two separate frames are not connected to each other and are separately mounted to the top 310 of the MCC section 106 such that the components projecting out of the MCC section 106 are disposed between the two separate frames. In another embodiment, the adapter plate 300 does not include the support plate 314, and the raised portion 606 only includes the portion of the frame 312.

The adaptor plate allows the same base design of the MCC 100 for use with either the expansion chamber 200 or the plenum 102. No design or manufacturing changes are needed for the MCC section 106 to be used with the expansion chamber 200 or the plenum 102. The adapter plate 300 is part of the MCC section 106 design. Depending on the requirements of the customer, the expansion chamber 200 or the plenum 102 may be attached to the MCC section 106 without having to go through extensive rework and/or ordering an entirely new MCC section.

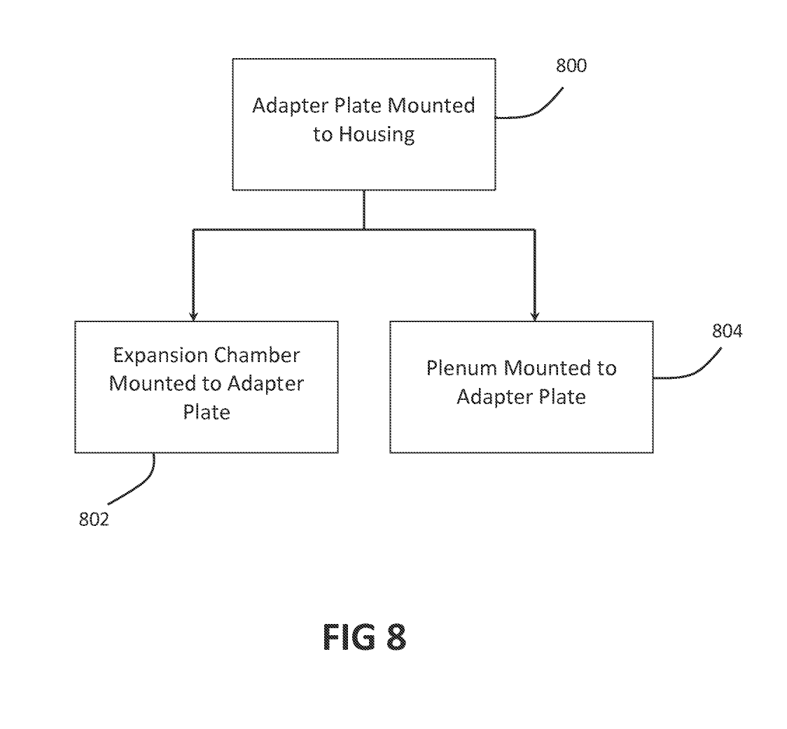

FIG. 8 shows a flow chart of one embodiment of a method of manufacturing an MCC. The method is implemented in the order shown, but other orders may be used. Additional, different, or fewer acts may be provided. For example, a plenum or expansion chamber is first removed from an existing MCC.

In act 800, an adapter plate is mounted to a top of a housing of an MCC. The housing includes the top, a bottom, and a plurality of sides. The adapter plate includes a frame. Both an expansion chamber and a plenum are mountable to the adapter plate.

The adapter plate may be formed out of a single piece of material. For example, the single piece of material may be 13 gauge steel. Other materials and other gauge steel may be used for the adapter plate. The adapter plate may be formed using casting, molding, forming, machining, or any number of other manufacturing processes. In one embodiment, the adapter plate may include more than one part (e.g., two parts). The two parts of the adapter plate may be formed from a single piece of material. The two parts, for example, may be formed from the same or different materials (e.g., different gauge steels), and a first of the two parts (e.g., a support plate) may be mounted to a second of the two parts (e.g., the frame) using screws, nuts and bolts, welding, or any number of other connectors.

A plurality of first apertures, a plurality of second apertures, and a plurality of third apertures may be formed in the adapter plate. The plurality of first apertures, the plurality of second apertures, and the plurality of third apertures may be positioned around the frame. In one embodiment, the plurality of first apertures, the plurality of second apertures, and the plurality of third apertures are formed in the adapter plate by drilling the plurality of first apertures, the plurality of second apertures, and the plurality of third apertures through the adapter plate. For example, the plurality of first apertures, the plurality of second apertures, and the plurality of third apertures are drilled through the adapter plate using a 5/16 inch drill bit. The plurality of first apertures, the plurality of second apertures, and the plurality of third apertures, respectively, may be drilled to extend partially or all the way through the adapter plate. In one embodiment, a tap is used to cut threads into the plurality of first apertures, the plurality of second apertures, the plurality of third apertures, or a combination thereof. In another embodiment, the plurality of first apertures, the plurality of second apertures, the plurality of third apertures, or a combination thereof is formed during the formation of the adapter plate (e.g., as part of the casting or the molding). A different sized bit and/or a different method for forming the apertures may be used. In one embodiment, the adapter plate does not include any apertures.

The plurality of first apertures may be formed in the adapter plate at positions corresponding to apertures in the plenum. The plurality of first apertures may include 16 or 26 apertures, for example. In other embodiments, the plurality of first apertures may include more or fewer apertures. The plurality of second apertures may be formed in the adapter plate at positions corresponding to apertures in the expansion chamber. The plurality of second apertures may include four apertures, for example. In other embodiments, the plurality of second apertures may include more or fewer apertures. The plurality of third apertures may be formed in the adapter plate at positions corresponding to apertures in the top of the housing. The plurality of third apertures may include four apertures, for example. In other embodiments, the plurality of third apertures may include more or fewer apertures.

The adapter plate may be positioned on the top of the housing. For example, a bottom of the adapter plate may be supported by the top of the housing. The adapter plate may be mounted to the top of the housing via the plurality of third apertures and the corresponding apertures in the top of the housing. The adapter plate may be mounted to the top of the housing using, for example, ¼-20 machine screws. In other embodiments, the adapter plate may be mounted to the top of the housing using, for example, nuts and bolts, rivets, welds, or other connectors. Other sized machine screws (e.g., 5/16-18) may be used to mount the adapter plate to the top of the housing. In another embodiment, the adapter plate is formed as an integral part of the top of the housing.

In act 802, the expansion chamber is mounted to the adapter plate via the plurality of second apertures spaced along the frame of the adapter plate. The expansion chamber may be positioned on a top of the adapter plate. For example, a bottom of the expansion chamber is supported by the top of the adapter plate. The expansion chamber may be mounted to the top of the adapter plate via the plurality of second apertures and corresponding apertures in the expansion chamber. The expansion chamber may be mounted to the top of the adapter plate using, for example, ¼-20 machine screws. In other embodiments, the adapter plate may be mounted to the top of the housing using, for example, other sized machine screws (e.g., 5/16-18), nuts and bolts, rivets, welds, or other connectors. The MCC may include a plurality of housings. The plurality of housings may support a plurality of expansion chamber sections, respectively. The plurality of expansion chamber sections may be attached to one another using, for example, machine screws or other connectors to form a single larger expansion chamber.

Alternatively, in act 804, the plenum is mounted to the adapter plate via the plurality of first apertures spaced along the frame of the adapter plate. The plenum may be positioned on the top of the adapter plate. For example, a bottom of the plenum may be supported by the top of the adapter plate. The plenum may be mounted to the top of the adapter plate via the plurality of first apertures and corresponding apertures in the plenum. The plenum may be mounted to the top of the adapter using, for example, 5/16-18 machine screws. In other embodiments, the plenum may be mounted to the adapter plate using, for example, different sized machine screws, nuts and bolts, rivets, welds, or other connectors.

In one embodiment, the first apertures are used only for mounting the plenum to the adapter plate, and the second apertures are used only for mounting the expansion chamber to the adapter plate. In another embodiment, at least some of the first apertures and/or at least some of the second apertures are used for both mounting the plenum to the adapter and mounting the expansion chamber to the adapter plate. In yet another embodiment, at least some of the first apertures and/or at least some of the second apertures are used for mounting the plenum and/or the expansion chamber to the adapter plate and for mounting the adapter plate to the housing of the MCC.

In one embodiment, while the MCC is installed at a location of a customer, the device mounted to the adapter plate (e.g., the expansion chamber or the plenum) is uninstalled, and a different device (e.g., the plenum or the expansion chamber) is mounted to the adapter plate. For example, the machine screws mounting the plenum to the adapter plate via the plurality of first apertures are removed, and the plenum is moved away from the top of the adapter plate (e.g., placed in storage). The expansion chamber, for example, is then positioned on the top of the adapter plate. The expansion chamber is mounted to the adapter plate via the plurality of second apertures.

The MCC may include the plurality of housings. The plurality of housings may support a plurality of plenum sections, respectively. The plurality of plenum sections may be attached to one another using, for example, machine screws or other connectors to form a single larger plenum. At a customer location, the plenum may be attached to a duct to carry away products of an arc flash within the MCC.

While the present invention has been described above by reference to various embodiments, it should be understood that many changes and modifications can be made to the described embodiments. It is therefore intended that the foregoing description be regarded as illustrative rather than limiting, and that it be understood that all equivalents and/or combinations of embodiments are intended to be included in this description.

1. An adapter plate of a motor control center (MCC) configured such that a plenum and an expansion chamber are mountable to the adapter plate, the adapter plate comprising:
a frame comprising:
a top, a bottom, and at least one side, the at least one side at least partially defining an outer perimeter of the frame;
at least one opening extending from the top to the bottom, the at least one opening at least partially defining an inner perimeter of the frame;
a plurality of first connection locations disposed along the frame, the plenum being mountable to the adapter plate at the plurality of first connection locations; and
a plurality of second connection locations disposed along the frame, the expansion chamber being mountable to the adapter plate at the plurality of second connection locations,
wherein the plenum is mounted to the adapter plate via the plurality of first connection locations, or the expansion chamber is mounted to the adapter plate via the plurality of second connection locations.

2. The adapter plate of claim 1, wherein the plurality of first connection locations comprises a plurality of first fastener apertures extending through the frame, and
wherein the plurality of second connection locations comprises a plurality of second fastener apertures extending through the frame.

3. The adapter plate of claim 2, wherein the plurality of first fastener apertures comprises at least sixteen first fastener apertures, and
wherein the plurality of second fastener apertures comprises four second fastener apertures.

4. The adapter plate of claim 3, wherein the plurality of first fastener apertures comprises twenty six first fastener apertures.

5. The adapter plate of claim 2, wherein the at least one side comprises a first side, a second side, a third side, and a fourth side,
wherein a first portion of first fastener apertures of the plurality of first fastener apertures is adjacent to the first side, and a second portion of first fastener apertures of the plurality of first fastener apertures is adjacent to the third side, and
wherein a first portion of second fastener apertures of the plurality of second fastener apertures is adjacent to the second side, and a second portion of second fastener apertures of the plurality of second fastener apertures is adjacent to the fourth side.

6. The adapter plate of claim 5, further comprising a support plate extending from the second side to the fourth side, between the first side and the third side,
wherein the support plate comprises a third fastener aperture, the third fastener aperture being positioned adjacent to the second side or the fourth side and extending through the support plate and the frame, and
wherein the adapter plate is mountable to an MCC section at the third fastener aperture.

7. The adapter plate of claim 6, wherein the frame and the support plate are made of 13 gauge steel.

8. A motor control center (MCC) usable with an expansion chamber and a plenum, the MCC comprising:
an MCC housing comprising a top, a bottom, and at least one side; and
an adapter plate supported by the housing at or adjacent to the top of the housing, the adapter plate comprising:
a frame comprising a top, a bottom, at least one side, and at least one opening, the at least one side at least partially defining an outer perimeter of the frame, the at least one opening extending from the top to the bottom of the frame and at least partially defining an inner perimeter of the frame;
a plurality of first apertures extending through the frame, the plenum being mountable to the adapter plate via the plurality of first apertures; and
a plurality of second apertures extending through the frame, the expansion chamber being mountable to the adapter plate at the plurality of second apertures.

9. The MCC of claim 8, further comprising a motor controller supported in the housing.

10. The MCC of claim 9, wherein the housing is a first housing, the adapter plate is a first adapter plate, the expansion chamber is a first expansion chamber, the plenum is a first plenum, and the motor controller is a first motor controller, and
wherein the MCC further comprises a second housing and a second adapter plate, the second housing supporting a second motor controller, a second expansion chamber and a second plenum being mountable to the second adapter plate.

11. The MCC of claim 10, further comprising the first plenum and the second plenum, the first plenum being mounted to the first adapter plate, the second plenum being mounted to the second adapter plate,
wherein the first plenum is mounted to the second plenum.

12. The MCC of claim 8, wherein the adapter plate comprises one or more third apertures extending through the frame,
wherein the top of the housing comprises one or more apertures, and
wherein the adapter plate is mountable to the top of the housing via the one or more third apertures extending through the frame and the one or more apertures of the housing.

13. The MCC of claim 8, wherein the adapter plate is the top of the housing.

14. The MCC of claim 8, further comprising the expansion chamber, the expansion chamber being mounted to the top of the frame of the adapter plate with screws through the plurality of second apertures.

15. The MCC of claim 8, further comprising the plenum, the plenum being mounted to the top of the frame of the adapter plate with screws via the plurality of first apertures.

16. The MCC of claim 8, wherein the at least one side of the frame comprises a first side, a second side, a third side, and a fourth side,
wherein a first portion of first apertures of the plurality of first apertures is adjacent to the first side, and a second portion of first apertures of the plurality of first apertures is adjacent to the third side, and
wherein a first portion of second apertures of the plurality of second apertures is adjacent to the second side, and a second portion of second apertures of the plurality of second apertures is adjacent to the fourth side.

17. The MCC of claim 16, further comprising a support plate extending from the second side to the fourth side, between the first side and the third side,
wherein the support plate comprises a third aperture, the third aperture being positioned adjacent to the second side or the fourth side and extending through the support plate and the frame, and
wherein the adapter plate is mountable to the housing at the third fastener aperture.

18. A method of manufacturing a motor control center (MCC), the MCC comprising an MCC housing and an adapter plate, the housing comprising a top, a bottom, and a plurality of sides, the adapter plate comprising a frame, the method comprising:
mounting the adapter plate to the top of the MCC housing, an expansion chamber and a plenum being mountable to the adapter plate; and
mounting the plenum to the adapter plate via a plurality of first fastener apertures spaced along the frame of the adapter plate; or
mounting the expansion chamber to the adapter plate via a plurality of second fastener apertures spaced along the frame of the adapter plate.

19. The method of claim 18, further comprising forming the adapter plate out of a single piece of material.

20. The method of claim 19, further comprising drilling the plurality of first fastener apertures and the plurality of second fastener apertures through the adapter plate.
